(19) United States
(12) Patent Application Publication
(10) Pub. No.: US 2023/0215985 A1
(43) Pub. Date: Jul. 6, 2023

(54) LIGHT-EMITTING DEVICE AND METHOD FOR PRODUCING THE SAME

(71) Applicant: XIAMEN SAN'AN OPTOELECTRONICS CO., LTD., Xiamen (CN)

(72) Inventors: Weichun TSENG, Xiamen (CN); Kang-Wei PENG, Xiamen (CN); Su-hui LIN, Xiamen (CN); Bin JIANG, Xiamen (CN); Mingchun TSENG, Xiamen (CN); Min HUANG, Xiamen (CN)

(21) Appl. No.: 18/174,192

(22) Filed: Feb. 24, 2023

Related U.S. Application Data
(63) Continuation-in-part of application No. PCT/CN2021/077104, filed on Feb. 20, 2021.

(51) Int. Cl. H01L 33/40; H01L 33/06; H01L 33/00

(52) U.S. Cl. CPC H01L 33/40; H01L 33/06; H01L 33/007; H01L 33/325

(57) ABSTRACT

A light-emitting device includes a light-emitting laminated structure, a first contact electrode, and an insulating layer. The light-emitting laminated structure has a first surface and a second surface opposite to the first surface, and includes a first semiconductor layer, a second semiconductor layer, and an active layer. The first contact electrode is disposed on the first surface and forms an ohmic contact with the light-emitting laminated structure. The insulating layer is disposed on the light-emitting laminated structure and covers the light-emitting laminated structure and the first contact electrode. The first contact electrode includes a first metal material that has a work function not less than 5 eV and that is in contact with the first surface. A method for producing the light-emitting device is also disclosed.

### CROSS-REFERENCE TO RELATED APPLICATION

This application is a bypass continuation-in-part (CIP) application of PCT International Application No. PCT/CN2021/077104, filed on Feb. 20, 2021. The entire content of the International patent application is incorporated herein by reference.

### FIELD

The disclosure relates to a semiconductor device and a method for producing the same, and more particularly to a light-emitting device and a method for producing the same.

### BACKGROUND

A proper contact resistance between an n-type gallium nitride (GaN) layer and an external electrode may be obtained by using a contact electrode having a metal structure made of titanium (Ti), aluminum (Al), gold (Au), etc. to interconnect the n-type gallium nitride (GaN) layer and the external electrode. Japanese Patent No. 3154364 B2 discloses a method of making an n-type contact electrode on an n-type semiconductor GaN layer, which involves sequentially forming a titanium layer and an aluminum layer on the n-type semiconductor GaN layer, followed by stacking a metal layer having a melting point higher than Al, such as Au, Ti, nickel (Ni), platinum (Pt), tungsten (W), molybdenum (Mo), chromium (Cr), copper (Cu), etc. Among the aforementioned metals, a gold layer in particular exhibits good performance for being capable of attaching firmly to Ti and Al.

In Japanese Patent No. 3154364 B2, the n-type contact electrode is formed by sequentially laminating the titanium layer, the aluminum layer, and the gold layer on the n-type semiconductor GaN layer which has been subjected to dry etching, following by a thermal treatment at a temperature greater than or equal to 400° C., e.g., at 600° C., so as to form the contact electrode on the n-type semiconductor GaN layer. By forming the contact electrode on the n-type semiconductor GaN layer, a good contact resistance and high adhesion strength between the contact electrode and the n-type semiconductor GaN layer could be obtained.

In view of the above, when the n-type semiconductor layer is a GaN layer, the n-type contact electrode having good contact resistance may be obtained.

For emitting light having an emission wavelength of 400 nm or less (i.e., in an ultraviolet region), the n-type semiconductor layer is required to be composed of an aluminum-containing group III-nitride. When the aluminum-containing group III-nitride is used with the aforesaid titanium/aluminum/gold layers, the contact resistance may become higher because the aluminum-containing group III-nitride has a smaller electron affinity as compared to GaN, so a Schottky barrier (defined by the difference between a work function of the contact electrode and an electron affinity of the n-type semiconductor layer) tends to be formed. That is to say, GaN has the electron affinity of approximately 2.7 eV and includes a metal that is unlikely to form the Schottky barrier. Even if the Schottky barrier is formed, the value of the Schottky barrier is still comparatively small. In contrast, the electron affinity of aluminum nitride (AlN), which is approximately 0.6 eV, is considered to be very small. Therefore, for a group III-nitride semiconductor containing a high concentration of Al, which has a small electron affinity, the Schottky barrier may easily be formed. That is to say, the formation of the Schottky barrier is inevitable in the abovementioned condition. In order to form an ohmic contact or achieve a condition as close as possible to an ohmic contact, it is necessary to select a suitable metal and make the width of the electron depletion layer (the n-type group III-nitride semiconductor layer with high aluminum concentration) smaller, so that an effective tunneling effect may be achieved.

### SUMMARY

Therefore, an object of the disclosure is to provide a light-emitting device and a method for producing the same that can alleviate or eliminate at least one of the drawbacks of the prior art.

According to the disclosure, the light-emitting device includes a light-emitting laminated structure, a contact electrode, and an insulating layer.

The light-emitting laminated structure has a first surface and a second surface opposite to the first surface. The light-emitting laminated structure includes a first semiconductor layer having a first electrical conductivity and containing aluminum, a second semiconductor layer having a second electrical conductivity that is different from the first electrical conductivity, and an active layer disposed between the first semiconductor layer and the second semiconductor layer. The active layer generates light via electron-hole recombination.

The contact electrode is disposed on the first surface and forms an ohmic contact with the light-emitting laminated structure.

The insulating layer is disposed on the light-emitting laminated structure and covers the light-emitting laminated structure and the contact electrode.

The contact electrode includes a first metal material that has a work function not less than 5 eV and that is in contact with the first surface.

According to the disclosure, the method of producing the light-emitting device includes the steps of:

(a) providing a light-emitting laminated structure that has a first surface and a second surface opposite to the first surface, and that includes a first semiconductor layer having a first electrical conductivity and containing aluminum, a second semiconductor layer having a second electrical conductivity that is different from the first electrical conductivity, and an active layer disposed between the first semiconductor layer and the second semiconductor layer, the active layer generating light via electron-hole recombination;

(b) forming a metal layer on the first surface, the metal layer including a first metal material and a second metal material disposed between the first metal material and the first surface, the first metal material having a work function not less than 5 eV; and

(c) subjecting the metal layer to an annealing treatment under a temperature ranging from 700° C. to 1200° C. so that the first metal material is brought into contact with the first surface, and the annealed metal layer is formed into a contact electrode.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIGS. 1 to 5 are cross-sectional schematic views illustrating a first embodiment of a method for producing a light-emitting device according to the disclosure.

FIG. 6 shows transmission electron microscope (TEM) images of a first contact electrode and a light-emitting laminated structure of the light-emitting device shown in FIG. 5.

FIG. 7 is a cross-sectional schematic view of a second embodiment of a method for producing a light-emitting device according to the disclosure.

FIG. 8 is a cross-sectional schematic view of a third embodiment of a method for producing a light-emitting device according to the disclosure.

FIG. 9 is an image showing the first contact electrode having metal agglomerations.

FIG. 10 is an image showing the first contact electrode having uniform metal distribution.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Referring to FIG. 5, an embodiment of a light-emitting device 1 according to the disclosure includes a light-emitting laminated structure 20, a first contact electrode 15b, and an insulating layer 17. The light-emitting laminated structure 20 has a first surface 20a and a second surface 20b opposite to the first surface 20a, and includes a first semiconductor layer 11 having a first electrical conductivity and containing aluminum, a second semiconductor layer 13 having a second electrical conductivity that is different from the first electrical conductivity, and an active layer 12 disposed between the first semiconductor layer 11 and the second semiconductor layer 13. The active layer 12 generates light via electron-hole recombination. The first contact electrode 15b is disposed on the first surface 20a of the light-emitting laminated structure 20, and forms an ohmic contact with the light-emitting laminated structure 20. In addition, the insulating layer 17 is disposed on the light-emitting laminated structure 20 and covers the light-emitting laminated structure 20 and the first contact electrode 15b. The first contact electrode 15b includes a first metal material 152 that has a work function not less than 5 eV and that is in contact with the first surface 20a.

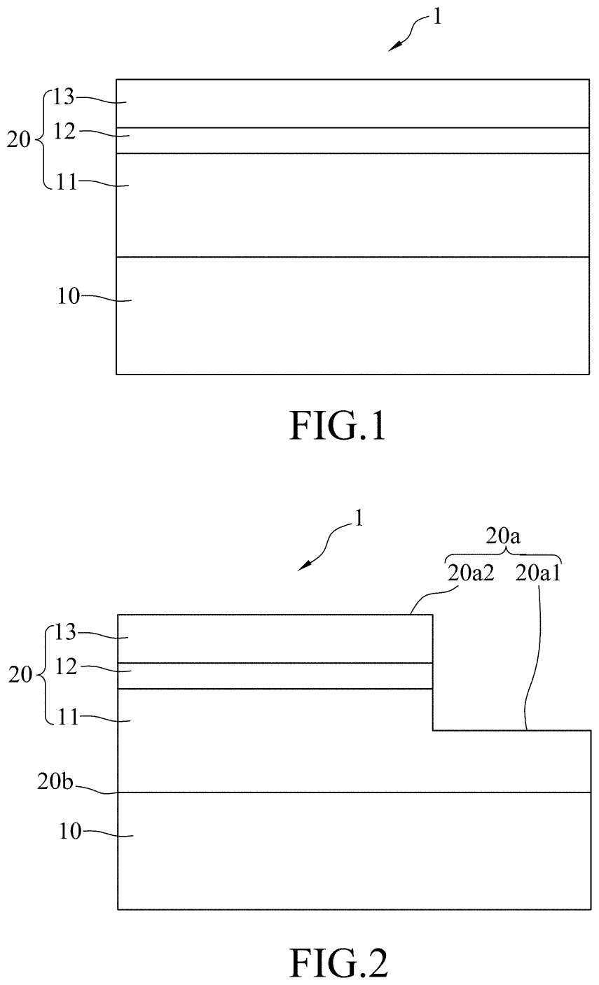

Referring to FIGS. 1 to 5, a first embodiment of a method for producing the aforesaid embodiment of the light-emitting device 1 according to the disclosure mainly includes the following steps (a), (b), and (c).

In step (a), the aforesaid light-emitting laminated structure 20 is provided. In step (b), a metal layer 15a is formed on the first surface 20a of the light-emitting laminated structure 20. The metal layer 15a includes the first metal material 152 and a second metal material 151 disposed between the first metal material 152 and the first surface 20a. In step (c), the metal layer 15a is subjected to an annealing treatment under a temperature ranging from 700° C. to 1200° C. so that the first metal material 152 is brought into contact with the first surface 20a, and the annealed metal layer is formed into the first contact electrode 15b.

Specifically, referring to FIG. 1, the light-emitting laminated structure 20 is disposed on a substrate 10. The substrate 10 may be a sapphire (aluminum oxide (Al₂O₃)) substrate, a silicon carbide (SiC) substrate, a silicon (Si) substrate, a zinc oxide (ZnO) substrate, a gallium nitride (GaN) substrate, a gallium arsenide (GaAs) substrate or a gallium phosphide (GaP) substrate, etc. In certain embodiments, the substrate 10 is a sapphire (Al₂O₃) substrate. Each of the first semiconductor layer 11, the active layer 12, and the second semiconductor layer 13 may be independently made of a gallium nitride-based material, e.g., GaN, indium gallium nitride (InGaN), aluminum gallium nitride (AIGaN), indium gallium aluminium nitride (InGaAlN), and combinations thereof. In certain embodiments, the aluminum in the first semiconductor layer 11 is present in an amount greater than 20 atom % based on 100 atom % of the first semiconductor layer 11. The first semiconductor layer 11 is a layer that provides electrons, and may be formed by doping with an n-type dopant (e.g., silicon (Si), germanium (Ge), selenium (Se), tellurium (Te), carbon (C), etc.). The second semiconductor layer 13 is a layer that provides electron holes, and may be formed by doping with a p-type dopant (e.g., magnesium (Mg), zinc (Zn), beryllium (Be), calcium (Ca), strontium (Sr), barium (Ba), etc.). In certain embodiments, the first semiconductor layer 11 is made of an aluminum-containing group III-nitride semiconductor material.

In certain embodiments, the first semiconductor layer 11 has a composition represented by InₓAl_{y}Ga_{1-x-y}N, wherein 0≤x<1 and 0.2<y≤1. The light-emitting laminated structure 20 having the InₓAl_{y}Ga_{1-x-y}N first semiconductor layer 11 may emit ultraviolet light and exhibit good performance.

An electron affinity of the aluminum-containing group III-nitride semiconductor material becomes smaller as the percentage of aluminum gets larger, resulting in an increased Schottky barrier height once the abovementioned semiconductor material is in contact with a metal. In such circumstances, an ohmic contact is hard to obtain. However, with the first metal material 152 used in the method according to the disclosure, even if the first semiconductor layer 11 is made of a group III-nitride semiconductor containing a high percentage of aluminum, a good ohmic contact may still be obtained. Thus, the disclosure is applicable to the first semiconductor layer 11 made of the group III-nitride semiconductor containing the high percentage of aluminum. In an exemplary embodiment, when the active layer 12 emits light having a wavelength in the UV-A region (i.e., 315 nm to 400 nm), the first semiconductor layer 11 has a composition represented by InₓAl_{y}Ga_{1-x-y}N, wherein 0≤x<1 and 0.2<y<0.4. In another exemplary embodiment, when the active layer 12 emits light having a wavelength in the UV-B region (i.e., 280 nm to 315 nm), the first semiconductor layer 11 has a composition represented by InₓAl_{y}Ga_{1-x-y}N, wherein 0≤x<1 and 0.4<y<0.65. In yet another exemplary embodiment, when the active layer 12 emits light having a wavelength in the UV-C region (i.e., less than 280 nm), the first semiconductor layer 11 has a composition represented by InₓAl_{y}Ga_{1-x-y}N, wherein 0≤x<1 and 0.65<y<1.

The active layer 12 is a layer in which the electrons provided by the first semiconductor layer 11 and the electron holes provided by the second semiconductor layer 13 recombine to emit light with a predetermined wavelength, and may be formed by a semiconductor film which includes a single quantum well structure or a multiple quantum well structure formed by alternatively and repeatedly stacked well layers and barrier layers. The active layer 12 may be made of materials having different compositions and/or ratios depending on the predetermined wavelength of the light.

Referring to FIG. 2, in this embodiment, the light-emitting laminated structure 20 of the light-emitting device 1 is subjected to a mesa-etching procedure, followed by a surface treatment. In the mesa-etching procedure, the second semiconductor layer 13, the active layer 12, and the first semiconductor layer 11 are partially removed to expose the first semiconductor layer 11 so that the first surface 20a having a first area 20a1 and a second area 20a2 is formed. The first area 20a1 is a part of the first semiconductor layer 11 and has the first electrical conductivity, and the second area 20a2 is a part of the second semiconductor layer 13 and has the second electrical conductivity. The surface treatment is conducted to improve an interfacial bonding between the light-emitting laminated structure 20 and the subsequently formed first contact electrode 15b. In certain embodiments, several surface treatments may be conducted. For example, the first surface 20a of the light-emitting laminated structure 20 is first subjected to a primary surface treatment by immersing the first surface 20a in a solution containing sulfuric acid (H₂SO₄), hydrogen peroxide (H₂O₂), and water (H₂O) having a mole ratio of 5:1:1 for approximately 10 minutes. Afterwards, the first surface 20a is washed with deionized water, followed by drying with nitrogen gas. Subsequently, a secondary surface treatment is carried out by immersing the first surface 20a in a buffered oxide etch (BOE) solution for approximately 2 minutes, followed by drying the first surface 20a. The aforementioned primary and secondary surface treatments may be selectively performed or even skipped depending on actual requirements.

Referring to FIG. 3, the metal layer 15a is formed on the first area 20a1 of the first surface 20a, that is to say, formed on the first semiconductor layer 11. The first metal material 152 has the work function not less than 5 eV. Generally, a work function of a metal varies depending on different measurement methods. The work function of this disclosure refers to the work functions recorded in JAP_48_4729 (1977). In certain embodiments, examples of the first metal material 152 include platinum (Pt, work function: 5.65 eV), gold (Au, work function: 5.10 eV), palladium (Pd, work function: 5.12 eV), nickel (Ni, work function: 5.15 eV) and combinations thereof. Moreover, in certain embodiments, examples of the second metal material 151 include titanium (Ti), aluminum (Al), chromium (Cr), rhodium (Rh), vanadium (V), tungsten (W), tantalum (Ta), ruthenium (Ru), and combinations thereof.

Referring to FIG. 4, the metal layer 15a is subjected to an annealing treatment under a temperature ranging from 700° C. to 1200° C. so that the first metal material 152 may diffuse into the second metal material 151 and be brought into contact with the first surface 20a, and the annealed metal layer is formed into the first contact electrode 15b. The first contact electrode 15b has a low contact resistance, thereby forming an ideal ohmic contact with the light-emitting laminated structure 20. During the annealing treatment that is conducted in high temperature, the first metal material 151 extracts nitrogen from the first semiconductor layer 11, which has the composition represented by InₓAl_{y}Ga_{1-x-y}N, wherein 0≤x<1 and 0.2<y≤1, causing a nitriding reaction to occur at the interface between the first metal material 151 and the first semiconductor layer 11 (i.e., the first area 20a1). Therefore, in certain embodiments, the first contact electrode 15b may further include a metal nitride. Because of the abovementioned nitriding reaction, the electron depletion layer (i.e., the first semiconductor layer 11) becomes thinner, making the Schottky barrier height lower. During the annealing treatment, the first metal material 152 diffuses/migrates into the second metal material 151, and then, at least a part of the first metal material 152 may make contact with the first area 20a1. That is to say, a part of the first metal material 152 may be in direct contact with the first semiconductor layer 11, thereby forming an interface at the first area 20a1 that is capable of exhibiting a tunneling effect. Hence, a low contact resistance is achieved and an ideal ohmic contact is realized. Moreover, the second metal material 151 also diffuses into the first metal material 152 during the annealing treatment, so that the metals in the first metal material 152 and the metals in the second metal material 151 may mix with each other. In this embodiment, a part of the second metal material (151) is in contact with the first area (20a1). That is to say, in this embodiment, the first metal material 152 and the second metal material 151 are distributed on the first area (20a1). In an exemplary embodiment, the second metal material 151 is titanium, and during the high-temperature annealing treatment, titanium extracts nitrogen from the first semiconductor layer 11, which has a composition presented by InₓAl_{y}Ga_{1-x-y}N, wherein 0≤x<1 and 0.2<y≤1, causing a nitriding reaction to occur at the interface between titanium and the first semiconductor layer 11 (i.e., the first area 20a1), so that the first contact electrode 15b may further include a metal nitride, namely, titanium nitride (TiN). In an exemplary embodiment, the first metal material 152 is platinum, and during the annealing treatment, platinum diffuses into the second metal material 151 and then migrates toward the first area 20a1 to make contact with the first area 20a1. That is to say, platinum is in contact with the first semiconductor layer 11. In addition, the second metal material 151 (Ti) also diffuses into the first metal material 152 (Pt) during the annealing treatment, so the platinum metals in the first metal material 152 and the titanium metals in the second metal material 151 are mixed with each other.

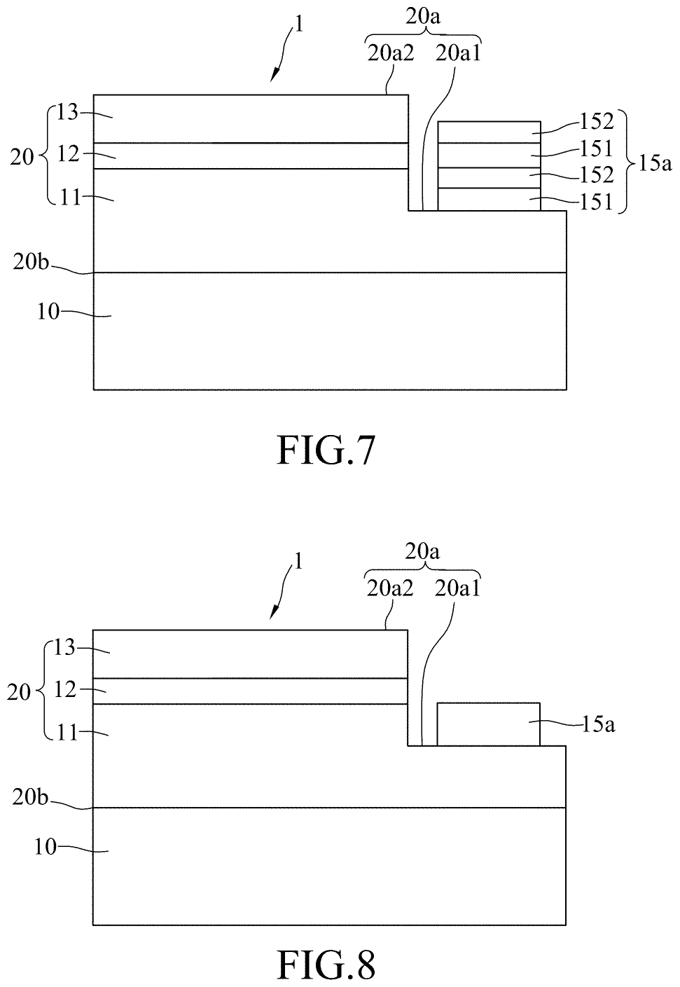

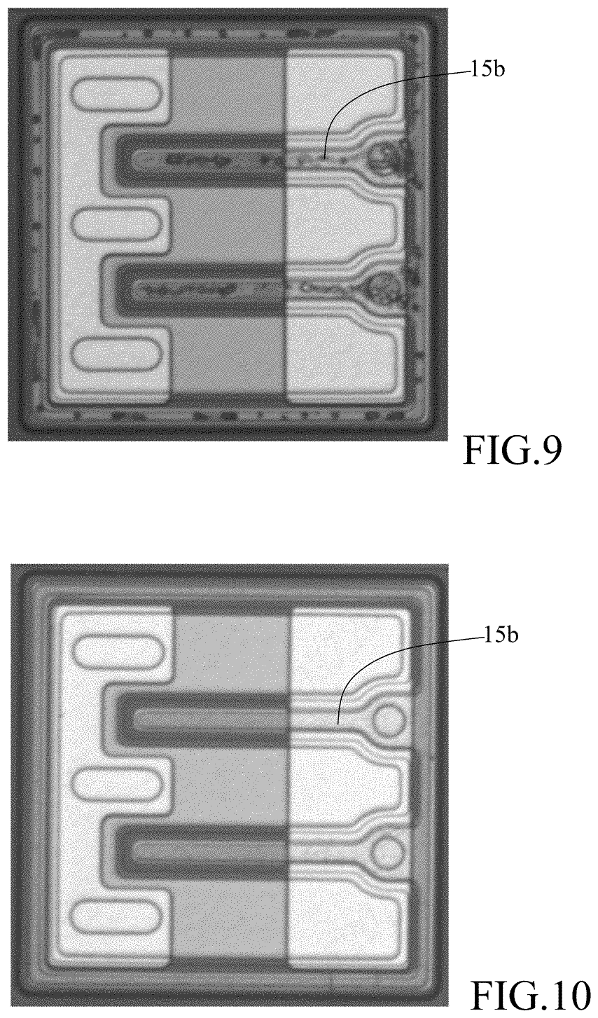

In certain embodiments, the second metal material 151 is a combination of titanium and aluminum, and during the high-temperature annealing treatment, aluminum causes a reaction between titanium and nitrogen in the InₓAl_{y}Ga_{1-x-y}N first semiconductor layer 11 (0≤x<1 and 0.2<y≤1), so as to form metal nitride (titanium aluminum nitride (AlTi₂N)) on the first area 20a1, which means that the metal nitride (AlTi₂N) is in direct contact with the first semiconductor layer 11. Meanwhile, titanium aluminide (TiAl₃) is also formed through the reaction between titanium and aluminum. In an exemplary embodiment, the first metal material 152 is gold, and during the annealing treatment ranging from 700° C. to 1200° C., gold diffuses into the second metal material 151 and then migrates toward the first area 20a1 to make contact with the first area 20a1. That is to say, gold is in direct contact with the first semiconductor layer 11. Referring to FIG. 9, after the annealing treatment, metal agglomerations (i.e., uneven metal distribution) tend to from in the first contact electrode 15b. In another exemplary embodiment, the first metal material 152 is platinum, and during the annealing treatment, platinum diffuses into the second metal material 151 and then migrates toward the first area 20a1 to make contact with the first area 20a1. That is to say, platinum is in contact with the first semiconductor layer 11. In addition, the second metal material 151 also diffuses into the first metal material 152 during the annealing treatment, so the first metal material 152 and the second metal material 151 are mixed with each other. Referring to FIG. 10, by using platinum as the first metal material 152, the first contact electrode 15b obtained after the annealing treatment has an uniform metal distribution, thereby increasing the yield as well as decreasing costs of the light-emitting device.

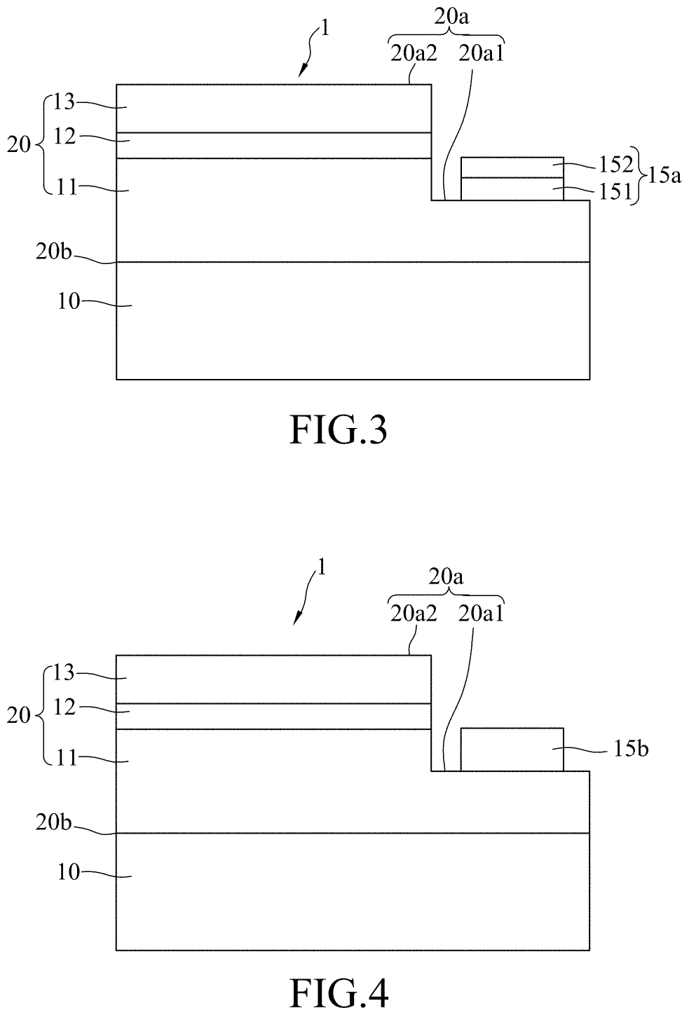

Referring to FIG. 6, TEM images of the first semiconductor layer 11 and the first contact electrode 15b at the first area 20a1 of FIG. 4 are shown, in which TEM image 6b shows the distribution of gallium (Ga), TEM image 6c shows the distribution of nitrogen (N), TEM image 6d shows the distribution of titanium (Ti), TEM image 6e shows the distribution of aluminum (Al), and TEM image 6f shows the distribution of platinum (Pt).

In order to further identify the element in each of the TEM images, the area where the element is distributed is circled in white dashed lines in FIG. 6. Referring to TEM image 6a, the area circled in white dashed lines is divided into a first layer 111 and a second layer 131, with a clear demarcation between the two layers, where the first area 20a1 is located. Referring to

TEM images 6b, 6c, and 6e, the first layer 111 contains gallium, nitrogen, and aluminum, indicating that the first layer 111 herein is the first semiconductor layer 11. Referring to TEM images 6d, 6e, and 6f, the second layer contains titanium, aluminum, and platinum, indicating that the second layer 131 herein is the first contact electrode 15b. Referring to TEM image 6c, nitrogen is distributed in the second layer 131 and is slightly spaced apart from the first layer 111, indicating that there exists metal nitrides in the first contact electrode 15b. Referring to TEM image 6d, it can be seen that titanium is distributed on the first area 20a1 and is in contact with the first semiconductor layer 11. Also, referring to TEM image 6e, it can be seen that aluminum is distributed on the first area 20a1 and is in contact with the first semiconductor layer 11. Referring to TEM image 6f, it can be seen that platinum diffuses into the second metal material 151 and makes contact with the first area 20a1. That is to say, platinum is in contact with the first semiconductor layer 11. It should be noted that, in TEM image 6f, a platinum distribution area is detected above the second layer 131, which is a layer formed in a subsequent procedure. Referring to TEM images 6d, 6e, and 6f, it can be seen that titanium, aluminum, and platinum are detected in the second layer 131 because of the diffusion of the metals during the annealing treatment.

In certain embodiments, the first metal material 152 is a combination of platinum and gold, and the second metal material 151 is a combination of titanium and aluminum. Due to the annealing treatment, platinum and gold diffuse into the second metal material 151 and make direct contact with the first area 20a1. That is to say, platinum and gold make direct contact with the first semiconductor layer 11. Moreover, the second metal material 151 also diffuses into the first metal material 152 during the annealing treatment, so that the first metal material 152 and the second metal material 151 may mix with each other. Similarly, during the high-temperature annealing treatment, aluminum contained in the second metal material 151 catalyzes a reaction between titanium contained in the second metal material 151 and nitrogen in the first semiconductor layer 11, so as to form metal nitride (titanium aluminum nitride (AlTi₂N)) on the first area 20a1. Meanwhile, titanium aluminide (TiAl₃) is also formed through the reaction between titanium and aluminum.

It should be understood that the disclosure is not limited to the aforementioned embodiments. In other words, the first metal material 152 and the second metal material 151 may be adjusted in other ways according to actual requirements.

In certain embodiments, another contact electrode having a structure similar to the first contact electrode 15b may be formed on the second semiconductor layer 13.

To emit light having a wavelength less than 400 nm, the first semiconductor layer 11 having a composition represented by InₓAl_{y}Ga_{1-x-y}N, where 0≤x<1 and 0.2<y≤1, has a high percentage of aluminum. Thus, the annealing treatment should be conducted under an appropriate temperature (e.g., not less than 700° C.) so that the first contact electrode 15b may have a good contact with the first semiconductor layer 11, thereby reducing contact resistance. In certain embodiments, the annealing treatment is conducted under a temperature ranging from 700° C. to 1200° C. If the temperature is less than 700° C., the desired ohmic contact and proper adhesion between the first contact electrode 15b and the first semiconductor layer 11 may not be obtained. If the temperature exceeds 1200° C., thermal decomposition of the first semiconductor layer 11 may occur. Thus, in consideration of the adhesion strength between the first semiconductor layer 11 and the first contact electrode 15b and the possibility of thermal decomposition occurring in the first semiconductor layer 11, the annealing treatment may be performed under the annealing temperature ranging from 700° C. to 1200° C. Furthermore, the annealing treatment may be performed under a fixed temperature within the foregoing range, or may be performed under temperatures varying within the foregoing range.

Duration of the annealing treatment may be adjusted according to the composition of the first semiconductor layer 11, the type and thickness of the first contact electrode 15b, etc. In an exemplary embodiment, the duration ranges from 30 seconds to 180 seconds. It is noted that the heating period during which the temperature raises to the annealing temperature is not included in the aforesaid duration. The heating period may be as short as possible. However, due to influences of the volume and performance of a heating device, the annealing temperature, etc., the duration of the annealing treatment may be less than 120 seconds, e.g., less than 60 seconds.

Generally, the external environment in which the annealing treatment is conducted is not particularly limited. However, to prevent a side reaction from happening between the external environment and the first semiconductor layer 11, the annealing treatment may be conducted under the protection of an inactive gas, for example, under a nitrogen atmosphere.

A thickness of the first contact electrode 15b is not particularly limited. In an exemplary embodiment, the first contact electrode 15b has a thickness of 10 nm or greater. In addition, the upper limit of the thickness of the first contact electrode 15b varies depending on the metal composition thereof. As a result, the optimal thickness of the first contact electrode 15b cannot be generally defined. However, considering production efficiency and costs, the thickness of the first contact electrode 15b may range from 100 nm to 300 nm.

Referring to FIG. 5, in certain embodiments, the light-emitting devices 1 further includes a transparent conductive layer 14, a second contact electrode 16, and an insulating layer 17. The transparent conductive layer 14 is formed on the second semiconductor layer 13. The transparent conductive layer 14 may be made of a material, e.g., indium tin oxide (ITO), zinc oxide (ZnO), aluminum-doped zinc oxide (AZO), fluorine-doped tin oxide (FTO), and indium molybdenum oxide (IMO). The transparent conductive layer 14 may be formed on the second semiconductor layer 13 using techniques such as electron beam evaporation or ion beam sputtering. The transparent conductive layer 14 may form an ohmic contact and exhibit lateral current spreading. The second contact electrode 16 is formed on the transparent conductive layer 14 and may include a material, e.g., Ni, Pt, Mg, Zn, Be, silver (Ag), Au, Ge, Cr, Ti, Al, tin (Sn), and combinations thereof. The insulating layer 17 is formed on the first contact electrode 15b, the second contact electrode 16, the transparent conductive layer 14, and the light-emitting laminated structure 20. In addition, the insulating layer 17 is formed with two through holes 171. In certain embodiments, the light-emitting devices 1 further includes a first electrode pad 18 and a second electrode pad 19 formed on the insulating layer 17 and respectively extend through the through holes 171, so that the first electrode pad 18 is electrically connected to the first semiconductor layer 11 via the first contact electrode 15b, and the second electrode pad 19 is electrically connected to the second semiconductor layer 13 via the second contact electrode 16 and the transparent conductive layer 14. In an exemplary embodiment, a material of each of the first electrode pad 18 and the second electrode pad 19 includes, e.g., chromium (Cr), platinum (Pt), gold (Au), nickel (Ni), titanium (Ti), aluminum (Al), gold-tin (AuSn), and combinations thereof. The insulating layer 17 may include, but not be limited to, a silicon dioxide (SiO₂) layer, a silicon nitride (Si₃N₄) layer, an aluminum oxide (Al₂O₃) layer, an aluminum nitride (AlN) layer, a trititanium pentoxide (Ti₃O₅) layer, a titanium dioxide (TiO₂) layer, a distributed Bragg reflector (DBR) layer, or combinations thereof. In an exemplary embodiment, the insulating layer 17 includes a DBR layer.

The present disclosure also provides a second embodiment of a method for producing the light-emitting device 1 according to the disclosure. The second embodiment is similar to the first embodiment except for the structure of the metal layer 15a.

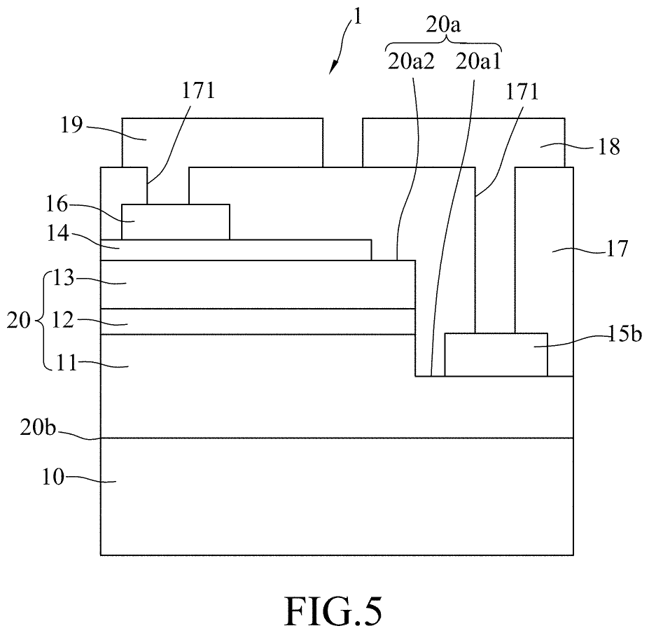

To be specific, referring to FIG. 7, in the second embodiment, the metal layer 15a includes a plurality of layer units stacked on each other. Each of the layer units includes the first metal material 152 and the second metal material 151. The metal layer 15a may include 2 to 10 layer units (there are two layer units in this embodiment). It is noted that, although the metal layer 15a in the second embodiment includes a plurality of the first metal material 152 and a plurality of the second metal material 151 that are alternately stacked on each other, the total thickness of the metal layer 15a remain unchanged compared to the first embodiment. In this embodiment, during the high-temperature annealing treatment, the first metal material 152 may more easily diffuse into the second metal material 151 and move toward and contact the first area 20a1, and the first metal material 152 and the second metal material 151 may be mixed more evenly with each other, thereby obtaining a lower contact resistance. The disclosure is not limited to this embodiment, and modifications depending on actual requirements may be made. For example, the number of the layer unit may vary based on actual requirements.

The present disclosure also provides a third embodiment of a method for producing the light-emitting device 1 according to the disclosure. The third embodiment is similar to the first embodiment except for the structure of the metal layer 15a.

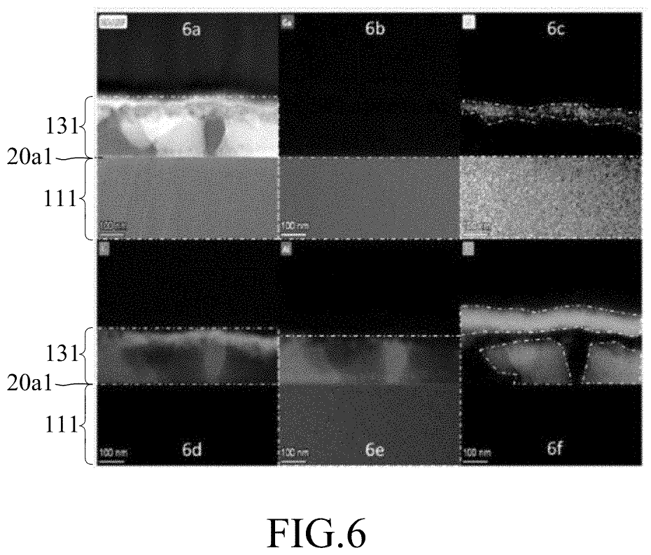

Referring to FIG. 8, in the third embodiment, the metal layer 15a is formed on the first semiconductor layer 11 using an alloy material (containing the first metal material 152 and the second metal material 151) as a target material or an evaporation material by sputtering or evaporation technique. Afterwards, the metal layer 15a is subjected to the annealing treatment so as to form a good contact with the first area 20a1 of the first surface 20a. In this embodiment, the second metal material 151 may also extract nitrogen from the first semiconductor layer 11, which has the composition represented by InₓAl_{y}Ga_{1-x-y}N, wherein 0≤x<1 and 0.2<y≤1, and a nitriding reaction may occur at the interface between the metal layer 15a and the first semiconductor layer 11 (i.e. the first area 20a1), so that the first contact electrode 15b subsequently formed may further include a metal nitride. Because of the abovementioned nitriding reaction, the electron depletion layer (i.e. the first semiconductor layer 11) becomes thinner, making the Schottky barrier height lower. In addition, the first metal material 152 may be distributed on the first area 20a1 and may be in direct contact with the first semiconductor layer 11. Hence, an interface that is capable of achieving the tunneling effect may form on the first area 20a1, which may reduce contact resistance.

In sum, with the contact electrode 15b having the first metal material 152 and the second metal material 151 and the first metal material 152 being in contact with the first area 20a1, an effective tunneling effect and decreased contact resistance may be achieved, thereby reducing the voltage and increasing the luminous efficiency of the light-emitting device 1.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a light-emitting laminated structure that has a first surface and a second surface opposite to said first surface, and that includes a first semiconductor layer having a first electrical conductivity and containing aluminum, a second semiconductor layer having a second electrical conductivity that is different from said first electrical conductivity, and an active layer disposed between said first semiconductor layer and said second semiconductor layer, said active layer generating light via electron-hole recombination,
a first contact electrode disposed on said first surface and forming an ohmic contact with said light-emitting laminated structure, and
an insulating layer disposed on said light-emitting laminated structure and covering said light-emitting laminated structure and said first contact electrode;
wherein said first contact electrode includes a first metal material that has a work function not less than 5 eV and that is in contact with said first surface.

2. The light-emitting device as claimed in claim 1, wherein said first surface has a first area having said first electrical conductivity and a second area having said second electrical conductivity, at least a part of said first metal material being in contact with said first area.

3. The light-emitting device as claimed in claim 2, wherein said first contact electrode further includes a second metal material that is in contact with said first area.

4. The light-emitting device as claimed in claim 3, wherein said first metal material and said second metal material are mixed with each other and are distributed on said first area.

5. The light-emitting device as claimed in claim 1, wherein said first contact electrode further includes a metal nitride.

6. The light-emitting device as claimed in claim 1, wherein said first metal material is selected from the group consisting of platinum, gold, palladium, nickel, and combinations thereof.

7. The light-emitting device as claimed in claim 1, wherein said first metal material is platinum.

8. The light-emitting device as claimed in claim 1, wherein said second metal material is selected from the group consisting of titanium, aluminum, chromium, rhodium, vanadium, tungsten, tantalum, ruthenium, and combinations thereof.

9. The light-emitting device as claimed in claim 1, further comprising a first electrode pad and a second electrode pad, said insulating layer including two through holes, said first electrode pad and said second electrode pad being disposed on said insulating layer and respectively extending through said two through holes, so that said first electrode pad is electrically connected to said first semiconductor layer via said first contact electrode, and said second electrode pad is electrically connected to said second semiconductor layer.

10. The light-emitting device as claimed in claim 1, wherein said light-emitting laminated structure emits light having a wavelength of less than 400 nm.

11. The light-emitting device as claimed in claim 1, wherein said aluminum in said first semiconductor layer is present in an amount greater than 20 atom % based on 100 atom % of said first semiconductor layer.

12. A method for producing a light-emitting device, comprising the steps of:
(a) providing a light-emitting laminated structure that has a first surface and a second surface opposite to the first surface, and that includes a first semiconductor layer having a first electrical conductivity and containing aluminum, a second semiconductor layer having a second electrical conductivity that is different from the first electrical conductivity, and an active layer disposed between the first semiconductor layer and the second semiconductor layer, the active layer generating light via electron-hole recombination;
(b) forming a metal layer on the first surface, the metal layer including a first metal material and a second metal material disposed between the first metal material and the first surface, the first metal material having a work function not less than 5 eV; and
(c) subjecting the metal layer to an annealing treatment under a temperature ranging from 700° C. to 1200° C. so that the first metal material is brought into contact with the first surface, and the annealed metal layer is formed into a first contact electrode.

13. The method as claimed in claim 12, wherein the first surface has a first area having the first electrical conductivity and a second area having the second electrical conductivity, at least a part of the first metal material being in contact with the first area.

14. The method as claimed in claim 13 wherein in step (c), the second metal material is in contact with the first area.

15. The method as claimed in claim 12, wherein in step (c), the first metal material and the second metal material are distributed on the first area.

16. The method as claimed in claim 12, wherein in step (c), the first contact electrode further includes a metal nitride.

17. The method as claimed in claim 12, wherein the first metal material is selected from the group consisting of platinum, gold, palladium, nickel, and combinations thereof.

18. The method as claimed in claim 12, wherein the first metal material is platinum.

19. The method as claimed in claim 12, wherein the second metal material is selected from the group consisting of titanium, aluminum, chromium, rhodium, vanadium, tungsten, tantalum, ruthenium, and combinations thereof.

20. The method as claimed in claim 12, further comprising, after step (c), step (d) of forming an insulating layer on the light-emitting laminated structure and the first contact electrode, and forming a first electrode pad and a second electrode pad on the insulating layer,
wherein
the insulating layer is formed with two through holes, and
the first electrode pad and the second electrode pad are disposed on the insulating layer and respectively extend through the two through holes, so that the first electrode pad is electrically connected to the first semiconductor layer via the first contact electrode, and the second electrode pad is electrically connected to the second semiconductor layer.

21. The method as claimed in claim 12, wherein in step (a), the light-emitting laminated structure emits light having a wavelength of less than 400 nm.

22. The method as claimed in claim 12, wherein the aluminum in the first semiconductor layer is present in an amount greater than 20 atom % based on 100 atom % of the first semiconductor layer.
